(19) United States
(12) Patent Application Publication
(10) Pub. No.: US 2010/0183224 A1
(43) Pub. Date: Jul. 22, 2010

(54) METHOD AND SYSTEM FOR EVALUATING CURRENT SPREADING OF LIGHT EMITTING DEVICE

(76) Inventors: June Sik Park, Yongin (KR); Bae Kyun Kim, Seongnam (KR); Dong Hoon Kang, Yongin (KR); Dong Yul Lee, Yongin (KR); Sang Su Hong, Suwon (KR)

Correspondence Address: MCDERMOTT WILL & EMERY LLP, 600 13TH STREET, N.W., WASHINGTON, DC, 20005-3096, US

(21) Appl. No.: 12/690,546

(22) Filed: Jan. 20, 2010

(30) Foreign Application Priority Data
Jan. 20, 2009 (KR) 10-2009-0004548

(51) Int. Cl. G06K 9/46; G01R 31/00

(52) U.S. Cl. 382/169; 382/194; 324/96

(57) ABSTRACT

Disclosed are a method and system for evaluating current spreading of a light emitting device. The method includes applying current to a light emitting device and acquiring a luminescence image corresponding to a digital signal, converting the luminescence image into a gray image, and determining the number of pixels having gray levels greater than a set threshold among pixels included in the luminescence image converted into the gray image, as a criterion for determining the degree of current spreading of the light emitting device.

The luminescent area of the light emitting device is quantified as an objective value on the two-dimensional plane by using an image processing technique, so that the degree of current spreading in the light emitting device can be evaluated.

### CROSS-REFERENCE TO RELATED APPLICATIONS

This application claims the priority of Korean Patent Application No. 10-2009-0004548 filed on Jan. 20, 2009, in the Korean Intellectual Property Office, the disclosure of which is incorporated herein by reference.

### BACKGROUND OF THE INVENTION

1. Field of the Invention

The present invention relates to a method and system for evaluating current spreading of a light emitting device, and more particularly, to a method and system for evaluating current spreading of a light emitting device which can quantitatively evaluate the degree of current spreading of a light emitting device on a two-dimensional plane by using an image processing technique.

2. Description of the Related Art

A semiconductor light emitting device, as one type of semiconductor device, can generate light of various colors by electron-hole recombination occurring at a p-n junction when current is applied. The LED has a longer useful life span, lower voltage, superior initial driving characteristics, high vibration resistance and high tolerance to repetitive power connection/disconnection. This has led to a continual increasing demand for the LED. Notably, of late, much attention has been drawn to a group III nitride semiconductor capable of emitting light having a short wavelength. A single nitride crystal constituting a light emitting device using this group III nitride semiconductor is formed on a substrate for growing a specific single crystal, such as a sapphire or SiC substrate.

FIG. 1 is a cross-sectional view depicting a general semiconductor light emitting device. Referring to FIG. 1, the semiconductor light emitting device includes an n-type semiconductor layer 12, an active layer 13 and a p-type semiconductor layer 14 grown on a sapphire substrate 11 in a sequential order. An n-type electrode 15a is disposed on the etched region of the n-type semiconductor layer 12, and a p-type electrode 15b is disposed on the p-type semiconductor layer 15b. In this case, the n-type and p-type electrodes 15a and 15b are disposed in a horizontal direction, causing narrow current flow as indicated by an arrow in FIG. 1. This narrow current flow increases the operating voltage Vf of the light emitting device, thus lowering current efficiency. Also, the light emitting device may become susceptible to electrostatic discharge. Therefore, semiconductor light emitting devices need to have current flow spreading over wide areas. In the field of semiconductor light emitting devices, a method is required by which the degree of current spreading can be evaluated quantitatively.

### SUMMARY OF THE INVENTION

An aspect of the present invention provides a method and system for evaluating current spreading of a light emitting device, which can quantitatively evaluate the degree of current spreading in a light emitting device on a two-dimensional plane by using an image processing technique.

According to an aspect of the present invention, there is provided a method for evaluating current spreading in a light emitting device, the method including: applying current to a light emitting device and acquiring a luminescence image corresponding to a digital signal; converting the luminescence image into a gray image; and determining the number of pixels having gray levels greater than a set threshold among pixels included in the luminescence image converted into the gray image, as a criterion for determining the degree of current spreading of the light emitting device.

The threshold may be 1/e of the maximum value of gray levels of the pixels included in the luminescence image.

The method may further include performing edge detection on the luminescence image to specify a luminescent region before the converting of the luminescence image into the gray image.

The method may further include performing histogram equalization on the luminescence image before the converting of the luminescence image into the gray image.

Alternatively, the method may further include performing histogram equalization on the luminescence image after the converting of the luminescence image into the gray image.

The method may further include performing edge detection on the luminescence image to specify a luminescent region between the converting of the luminescence image into the gray image and the performing of the histogram equalization.

Alternatively, the method may further include performing edge detection on the luminescence image to specify a luminescent region before the converting of the luminescence image into the gray image and the performing of the histogram equalization.

The acquiring of the luminescence image of the light emitting device may include acquiring a luminescence image of the light emitting device by using a confocal scanner electroluminescence spectral microscope.

The light emitting device may include at least two electrodes. The acquiring of the luminescence image of the light emitting device may include acquiring a luminescence image of the light emitting device, the luminescence image including a luminescent region between the at least two electrodes.

According to another aspect of the present invention, there is provided a system for evaluating current spreading of a light emitting device, including: an image acquisition unit acquiring a luminescence image corresponding to a digital signal from a light emitting device; an image conversion unit converting the luminescence image into a gray image; and a data processing unit counting the number of pixels having gray levels greater than a set threshold among pixels included in the luminescence image converted into the gray image.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view showing a general semiconductor light emitting device;

FIG. 2 is a flowchart showing the operational principle of a system for evaluating current spreading of a light emitting device, according to an exemplary embodiment of the present invention;

FIGS. 3 through 7 show the respective actual images of operations shown in FIG. 2;

FIG. 8 illustrates the configuration of a confocal scanner electroluminescence microscope which can be employed as an image acquisition unit according to an exemplary embodiment of the present invention; and

FIG. 9 is a graph associated with an example of the actual application of the method of evaluating current spreading according to the present invention.

### DETAILED DESCRIPTION OF THE PREFERRED EMBODIMENT

Exemplary embodiments of the present invention will now be described in detail with reference to the accompanying drawings.

The invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the shapes and sizes of elements maybe exaggerated for clarity. Like reference numerals in the drawings denote like elements.

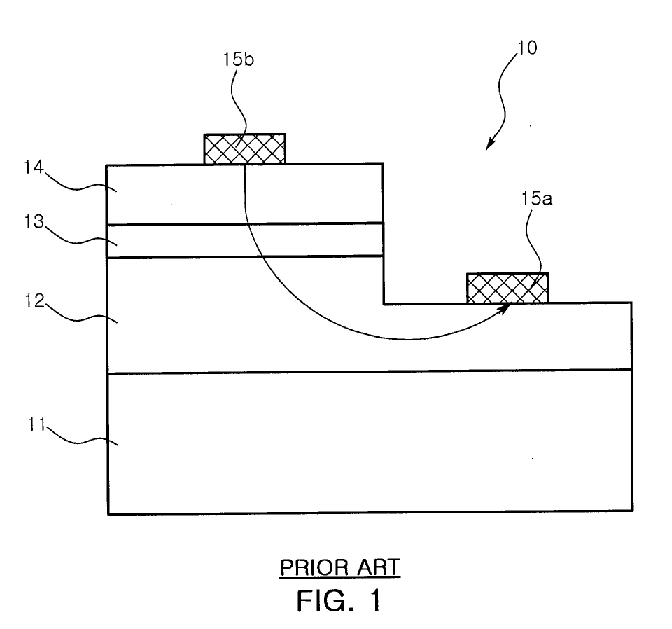

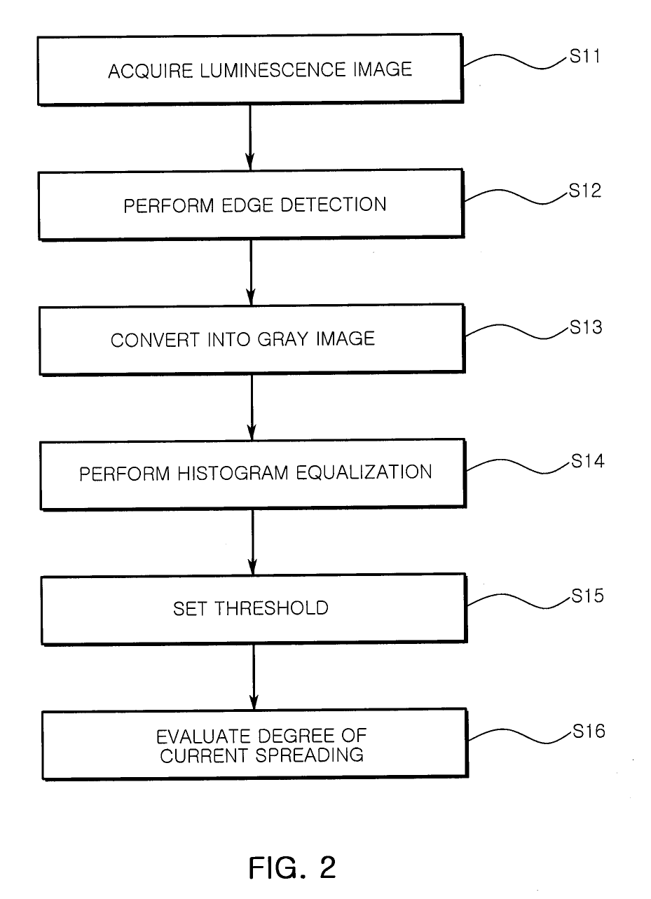

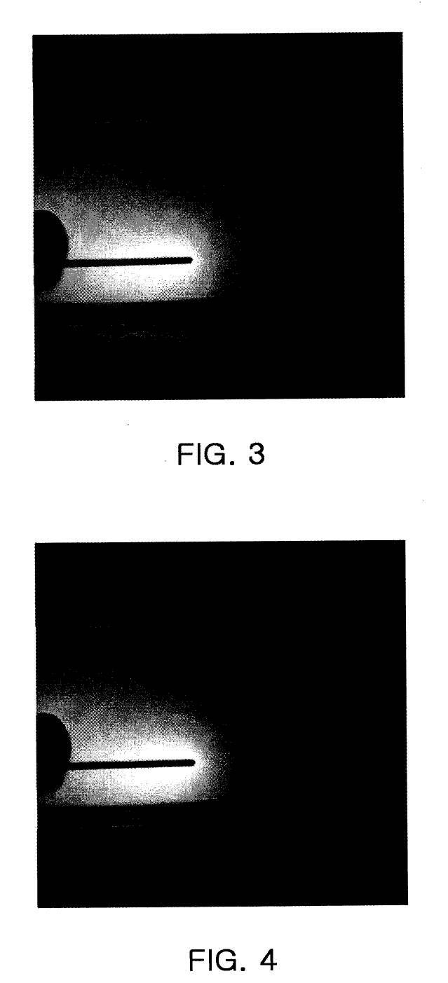

FIG. 2 is a flowchart showing the operational principle of a system for evaluating current spreading of a light emitting device according to an exemplary embodiment of the present invention. FIGS. 3 through 7 illustrate the respective actual images of operations shown in FIG. 2. According to this embodiment, the system for evaluating current spreading of a light emitting device includes an image acquisition unit, an image conversion unit, and a data processing unit. In a first operation S11, a luminescence image is acquired by the image acquisition unit. The image acquisition unit stores the luminescence image of the light emitting device to which current is applied, in the form of a digital signal on which image processing can be performed by an operation unit. In this case, the image acquisition unit applies current to the light emitting device having a structure as shown in FIG. 1, and acquires a luminescence image including a luminescent region between two electrodes. The luminescent region may refer to a region occupied by a light emitting device.

According to this embodiment, the degree of current spreading is evaluated based on the luminescent area of the light emitting device. That is, to evaluate the degree of current spreading, a luminescent area, which may be considered as a two-dimensional evaluation factor, is used, not a current spreading length which may be considered as a one-dimensional evaluation factor. For this reason, in this embodiment, a high definition image of the luminescent region of the light emitting device needs to be obtained, and the luminescence image needs to undergo proper image processing in order to define a final luminescent region.

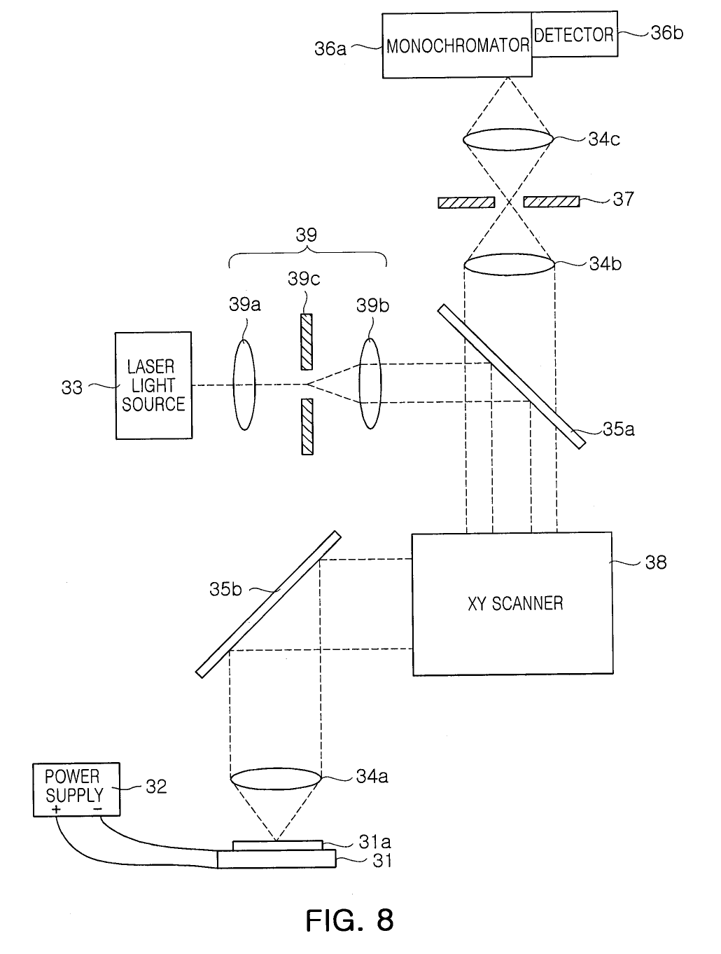

As for the image acquisition unit, a confocal scanner electroluminescence microscope may be used. FIG. 8 illustrates an example of a confocal scanner electroluminescence microscope usable as the image acquisition unit according to the present invention. Referring to FIG. 8, the confocal scanner electroluminescence microscope includes a power supply 32, a support 31, a confocal microscope part 34a, 34b, 34c and 37, a detection part 36a and 36b, a laser light source 33, and an XY scanner 38. An object 31a containing a luminescent material is placed on the support 31. To use the method of evaluating current spreading according to this embodiment, the object 31a may be a semiconductor light emitting device such as a light emitting diode (LED). The object 31a is not simply disposed on the support 31 but is connected to the power supply 32 to receive power for light emission. The power supply 32, although connected directly to the support 31, is electrically connected to the object 31a due to the electrical connection between the support 31 and the object 31a, thereby enabling the object 31a to emit light electrically.

A confocal lens 34a, a pinhole 37, and the detection part 36a and 36b are disposed above the support 31 on which the object 31a is placed, thereby constituting a confocal microscope. The confocal lens 34a receives light emitted from the object 31a. The light emitted from the object 31a passes through the confocal lens 34a to travel as parallel light rays, and is collected by a condenser lens 34b and guided to the pinhole 37. A focal point is formed on the surface of the object 31a by the confocal lens 34a. The pinhole 37 is confocal with the focal point. By using the confocal lens 34a, only the light emitted from the focal point formed on the surface of the object 31a can be guided to the detection part 36a and 36b. The pinhole 37 only allows the reception of light emitted from a specific point of the object 31a, thereby enhancing the image resolution of the confocal microscope. That is, the pinhole 37 only allows the passage of light emitted from the focal point on the surface of the object 31a and blocks light emitted from an adjacent region. Accordingly, a luminescence image for only a desired region can be obtained, even in the case that the object 31a emits light with a high luminance level.

Light, having passed through the pinhole 37, is collected by the condenser lens 34c and guided to the detection part 36a and 36b. The detection part 36a and 36b includes a monochromator 36a that disperses received photons by wavelength, and a detector 36b that measures the distribution of the dispersed light. The light distribution, detected by the detector 36b, is sent to a display unit such as a monitor connected to the outside. The monochromator 36a has a dispersion optical system such as a prism or a diffraction grating disposed therein, thereby dispersing light propagating through the pinhole 37 for each wavelength. The light dispersed in this fashion is detected by the detector 36b. The detector 36b, if controlled to detect a certain portion of the dispersed wavelengths, produces an electroluminescence spectrum of the focal point formed on the target surface of the object 31a.

The XY scanner 38 scans the surface of the object 31a along a predetermined track on the surface of the object 31a. In the case of the absence of the XY scanner 38, this two-dimensional scanning may be realized by transferring an optical structure such as the support 31 where the object 31a is mounted, or the confocal lens 34a. In particular, a known galvano scanner may be employed as the XY scanner 38. As described above, the surface of the object 31a is scanned, so that the monochromator 36a and the detector 36b can obtain an electroluminescence spectral image of the entire surface of the object 31a and an electroluminescence spectrum at a predetermined point of the object 31a.

After scanning is performed along the surface of the object, the focal point is shifted in the depth direction of the object 31a to obtain optical information about another target surface. Such a vertical transfer unit is implemented by transferring the confocal lens 34a vertically with respect to the surface of the object 31a and adjusting the vertical position of the confocal point. As described above, two-dimensional scanning for the one target surface and additional selective two-dimensional scanning for another target surface may be performed repeatedly to enable information about a three-dimensional space to be interpreted. Particularly, in the case of measuring a nitride semiconductor wafer, an active layer is three-dimensionally analyzable. Accordingly, a luminescence wavelength in the overall active layer may be evaluated based on a high three-dimensional resolution.

The laser light source 33 needs to generate a beam with energy capable of exciting a luminescent material included in the object 31a. Also, the laser light source 33 needs to irradiate a subpico-second pulse beam to excite the luminescent material by single or multiple photons. Lenses 39a and 39b and a pinhole 39c are disposed in front of the laser light source 33. Therefore, the beam generated from the laser light source 33 is directed more precisely toward a light director 35a. The confocal lens 34a serves as a light collector for imaging the beam from the laser light source 33 on the target surface of the object 31a disposed on the support 31 and as a light receiver for receiving photons generated from the object 31a. In this structure, a vertical transfer unit (not shown) may be further provided to vertically transfer the confocal lens 34a so that the target surface moves in the thickness direction of the object 31a.

The light director 35a directs the beam from the laser light source 33 toward the confocal lens 34a, and also directs light emitted from the object 31a toward the condenser lens 34b for the collection of light in the pinhole 37. The light director 35a may be implemented as a dichromatic beam splitter. The dichromatic beam splitter has selectivity for wavelength. According to this embodiment, the dichromatic beam splitter is disposed to reflect the beam from the laser light source 33, and transmit the light emitted from the object 31a. A mirror 35b, disposed between the XY scanner 38 and the confocal lens 34a, operates differently from the light director 35a. The mirror 35b reflects both the laser beam passing through the XY scanner 38 and the light emitted from the object 31a to thereby alter an optical path.

In this fashion, the confocal scanner electroluminescence spectral microscope dramatically enhances spatial resolution over a conventional CCD-based electroluminescence image measuring device. The confocal scanner electroluminescence spectral microscope is a unique device for analyzing electroluminescent device characteristics, incorporating the function of a conventional luminescence spectrum device and the function of a confocal laser scanning fluorescent microscope. The confocal scanner electroluminescence spectral microscope, described in the present invention, allows for simultaneous measurement, analysis and comparison of the structural shape, the electroluminescence distribution profile, the electroluminescence spectrum distribution profile, the optical luminescence distribution profile, the optical luminescence spectrum distribution profile with respect to the electroluminescent device as the object. FIG. 3 illustrates an example of the luminescence image of a light emitting device, which is obtained by this confocal scanner electroluminescence microscope. In the image depicted in FIG. 3, darker portions on the left and right sides of the image correspond to electrodes, respectively, and each electrode includes a round electrode pad, and a rod-shaped electrode finger.

Referring to FIG. 2, in a second operation S12, edge detection for detecting a luminescent region is performed on the luminescence image of FIG. 3 acquired by the confocal scanner electroluminescence microscope or the like. FIG. 4 illustrates an image obtained by this edge detection process. The edge detection may be performed by utilizing an edge detection algorithm (e.g., the Sobel algorithm, the Robert algorithm or the like) known in the art. For example, a 3×3 edge-detection mask may be applied to the entire luminescence image. In this case, an edge detection region may be set to initially have a shape, such as a rectangle, a triangle or a circle, corresponding to the shape of the light emitting device. According to this embodiment, the edge is detected directly from a color image. However, the edge detection may be performed after a conversion process into a gray image or a histogram equalization process to be described later.

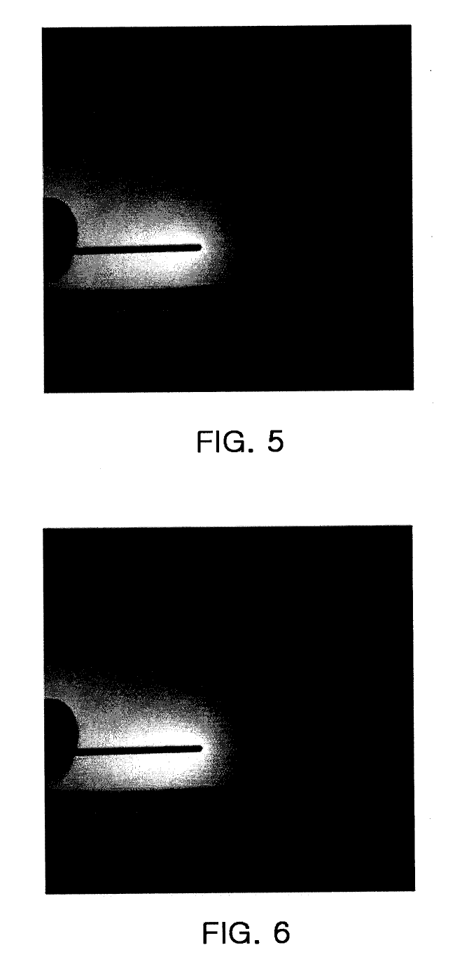

Subsequently, in a third operation S13, the luminescence image, a color image, is converted into a gray image, based on the brightness value (i.e., the gray level) of each pixel. By converting the luminescence image into the gray image (hereinafter, also referred to as ‘gray image conversion’), a brightness value of each pixel may determine whether or not each pixel corresponds to the luminescent region. The gray image conversion process may be performed after the edge detection process, as in this embodiment. However, the gray image conversion may also be performed before the edge detection process or after a histogram equalization process to be described later. An image obtained by the gray image conversion process is as shown in FIG. 5.

Subsequently in a fourth operation S14, histogram equalization is performed on the converted gray luminescence image. The histogram equalization expands the gray value distribution (i.e., dynamic rage) of the gray image to the range of 0 to 255. This may magnify the contrast of the luminescence image, thereby facilitating the determination of the luminescent region. In the histogram equalization, the minimum and maximum values of the gray values are set to 0 and 255 respectively and in-between values are properly increased or reduced, thereby converting the gray value of each pixel. However, the histogram equalization process is not necessarily required in this present invention, and may be omitted according to embodiments. Also, the histogram equalization process may be performed first after the color image is acquired, not after the edge detection and the gray image conversion as in this embodiment. An image obtained by the histogram equalization is as shown in FIG. 6.

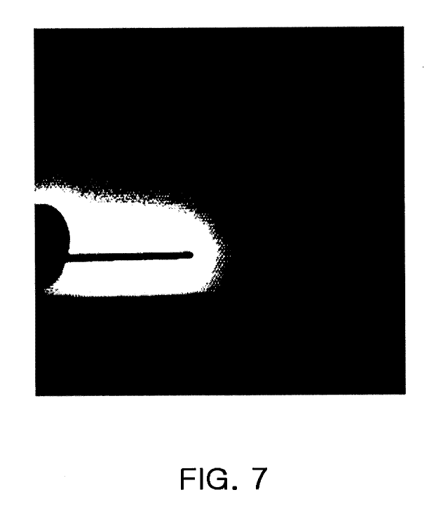

Next, in a fifth operation S15, a threshold is set for the determination of the luminescent region in the luminescence image. According to this embodiment, a value corresponding to 1/e of the maximum gray value is set to a threshold, and a pixel having a gray value greater than the threshold is determined as being included in the luminescent region. A pixel determined as part of the luminescent region in this manner (i.e., a pixel with a gray value greater than 1/e) is set to a gray value of 255, and a pixel determined as not being included in the luminescent region (i.e., a pixel with a gray value not exceeding 1/e) is set to a gray value of 0, thereby obtaining a binary image as shown in FIG. 7. Through the series of above operations, the image depicted in FIG. 7 is acquired, and the bright region is determined to be the luminescent region. Here, the threshold may be properly changed as occasion arises.

Thereafter, in a sixth operation S16, the degree of current spreading in the light emitting device is evaluated based on the luminescent area of the luminescence image in which the luminescent region is defined. That is, by using the data processing unit, the number of pixels having brightness levels which are equal to or smaller than a predetermined value is counted, and this is defined as the luminescent area. The size of the luminescent area is evaluated quantitatively as to the magnitude of current spreading. The image obtained according to this embodiment is an image at 20× magnification, and the number of bright pixels in FIG. 7 is 28,939. Thus, the current spreading area maybe set to 28,939 μm². By evaluating the degree of current spreading based on the luminescent area, an objective criterion regarding current spreading may be presented, regardless of the varied shapes, locations and materials of electrodes. In detail, in the case that the degree of current spreading is measured based on length, it is difficult to present an objective and consistent criterion when the positions and shapes of electrodes are different. Thus, the present invention serves to solve this difficulty.

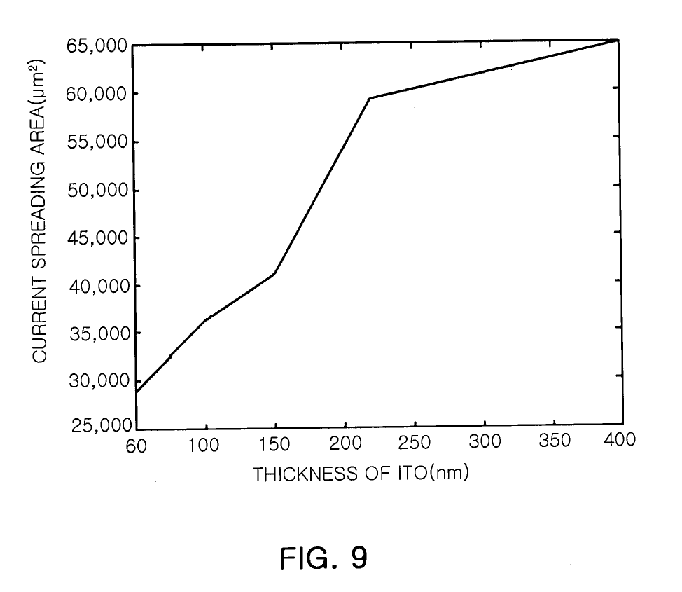

FIG. 9 is a graph associated with an example of the actual application of the method of evaluating current spreading of the present invention, used for a semiconductor light emitting device. In detail, the graph shows changes in current spreading area according to the thicknesses of an indium tin oxide (ITO) transparent electrode formed between a p-type semiconductor layer and a p-type electrode. Referring to FIG. 9, it can be seen that the current spreading area increases with an increase in the thickness of the ITO transparent electrode. This may be interpreted as being caused by the induction of current in a lateral direction due to the increase in the ITO thickness. As can be seen from the result of FIG. 9, the present invention may present an objective and easy-to-use evaluation criterion for determining to what extent the current spreads in the light emitting device.

As set forth above, according to exemplary embodiments of the invention, the luminescent area of the light emitting device is quantified as an objective value on a two-dimensional plane by using an image processing technique, so that the degree of current spreading of the light emitting device can be evaluated. Particularly, by using the method of evaluating current spreading of the light emitting device according to the exemplary embodiments of the present invention, quantitative evaluation can be performed based on a consistent criterion even in various environments affected by the shape of the light emitting device or the electrode, the position of the electrode, the properties of the material or the like.

While the present invention has been shown and described in connection with the exemplary embodiments, it will be apparent to those skilled in the art that modifications and variations can be made without departing from the spirit and scope of the invention as defined by the appended claims.

What is claimed is:

1. A method of evaluating current spreading in a light emitting device, the method comprising:
applying current to a light emitting device and acquiring a luminescence image corresponding to a digital signal;
converting the luminescence image into a gray image; and
determining the number of pixels having gray levels greater than a set threshold among pixels included in the luminescence image converted into the gray image, as a criterion for determining the degree of current spreading of the light emitting device.

2. The method of claim 1, wherein the threshold is 1/e of the maximum value of gray levels of the pixels included in the luminescence image.

3. The method of claim 1, further comprising performing edge detection on the luminescence image to specify a luminescent region before the converting of the luminescence image into the gray image.

4. The method of claim 1, further comprising performing histogram equalization on the luminescence image before the converting of the luminescence image into the gray image.

5. The method of claim 1, further comprising performing histogram equalization on the luminescence image after the converting of the luminescence image into the gray image.

6. The method of claim 4, further comprising performing edge detection on the luminescence image to specify a luminescent region between the converting of the luminescence image into the gray image and the performing of the histogram equalization.

7. The method of claim 5, further comprising performing edge detection on the luminescence image to specify a luminescent region between the converting of the luminescence image into the gray image and the performing of the histogram equalization.

8. The method of claim 4, further comprising performing edge detection on the luminescence image to specify a luminescent region before the converting of the luminescence image into the gray image and the performing of the histogram equalization.

9. The method of claim 5, further comprising performing edge detection on the luminescence image to specify a luminescent region before the converting of the luminescence image into the gray image and the performing of the histogram equalization.

10. The method of claim 1, wherein the acquiring of the luminescence image of the light emitting device comprises acquiring a luminescence image of the light emitting device by using a confocal scanner electroluminescence spectral microscope.

11. The method of claim 1, wherein the light emitting device includes at least two electrodes, and
the acquiring of the luminescence image of the light emitting device comprises acquiring a luminescence image of the light emitting device, the luminescence image including a luminescent region between the at least two electrodes.

12. A system for evaluating current spreading of a light emitting device comprising:
an image acquisition unit acquiring a luminescence image corresponding to a digital signal from a light emitting device;
an image conversion unit converting the luminescence image into a gray image; and
a data processing unit counting the number of pixels having gray levels greater than a set threshold among pixels included in the luminescence image converted into the gray image.

13. The system of claim 12, wherein the image acquisition unit is a confocal scanner electroluminescence spectral microscope.

14. The system of claim 12, wherein the threshold is 1/e of the maximum value among gray levels of the pixels included in the luminescence image.
